(19) United States
(12) Patent Application Publication
(10) Pub. No.: US 2025/0081856 A1
(43) Pub. Date: Mar. 6, 2025

(54) SEMICONDUCTOR DEVICE AND METHOD FOR FABRICATING THE SAME

(71) Applicant: SK hynix Inc., Icheon-si (KR)

(72) Inventor: Soo Man SEO, Icheon-si (KR)

(21) Appl. No.: 18/444,335

(22) Filed: Feb. 16, 2024

(30) Foreign Application Priority Data
Aug. 31, 2023 (KR) 10-2023-0115232

(51) Int. Cl. H10N 50/10; H10B 61/00; H10N 50/01; H10N 59/00

(52) U.S. Cl. CPC H10N 50/10; H10B 61/10; H10N 50/01; H10N 59/00

(57) ABSTRACT

A semiconductor device and a method for fabricating the same are provided. The semiconductor device includes: a substrate; a first magnetic tunnel junction structure disposed over a portion of the substrate and including a first free layer; a first hard mask layer disposed over the first free layer; a second magnetic tunnel junction structure disposed over another portion of the substrate and including a second free layer having a thickness smaller than a thickness of the first free layer; a second hard mask layer disposed over the second free layer; and a doped layer interposed between the second free layer and the second hard mask layer and having conductivity.

### CROSS-REFERENCE TO RELATED APPLICATION

This patent document claims the priority and benefits of Korean Patent Application No. 10-2023-0115232 filed on Aug. 31, 2023, which is incorporated herein by reference in its entirety.

### TECHNICAL FIELD

The technology disclosed in this patent document relates to a semiconductor technology, and particularly, to a semiconductor device including a magnetic tunnel junction and a method for fabricating the same.

### BACKGROUND

The recent trend toward miniaturization, low power consumption, high performance, and multi-functionality in the electrical and electronics industry has compelled the semiconductor manufacturers to focus on high-performance, high capacity semiconductor devices. Examples of such high-performance, high-capacity semiconductor devices include semiconductor devices that can store data by switching between different resistance states according to an applied voltage or current, such as an RRAM (resistive random access memory), a PRAM (phase change random access memory), an FRAM (ferroelectric random access memory), an MRAM (magnetic random access memory), and an electronic fuse (E-fuse).

### SUMMARY

In an embodiment, a semiconductor device may include: a substrate; a first magnetic tunnel junction structure disposed over a portion of the substrate and including a first free layer; a first hard mask layer disposed over the first free layer of the first magnetic tunnel junction; a second magnetic tunnel junction structure disposed over another portion of the substrate and including a second free layer having a thickness smaller than a thickness of the first free layer; a second hard mask layer disposed over the second free layer of the second magnetic tunnel junction; and a doped layer interposed between the second free layer of the second magnetic tunnel junction and the second hard mask layer and configured to exhibit an electrical conductivity.

In another embodiment, a semiconductor device may include: a substrate; a first magnetic tunnel junction structure disposed over a portion of the substrate and including a first free layer; a first hard mask layer disposed over the first free layer; a second magnetic tunnel junction structure disposed over another portion of the substrate and including a second free layer having a thickness smaller than a thickness of the first free layer; and a second hard mask layer disposed over the second free layer, wherein a thickness of the first hard mask layer is smaller than a thickness of the second hard mask layer.

In another embodiment, a method for fabricating a semiconductor device, may include: forming a magnetic tunnel junction layer over a substrate, the magnetic tunnel junction layer including a pinned layer, a tunnel barrier layer, and a free layer; forming a sacrificial hard mask layer over the free layer to cover at least a first region where a first magnetic tunnel junction structure is to be formed and to expose at least a second region where a second magnetic tunnel junction structure is to be formed; forming a doped region having a thickness smaller than a thickness of the free layer by doping a portion of the free layer exposed by the sacrificial hard mask layer with a dopant that decreases a magnetism of the free layer; removing the sacrificial hard mask layer; forming a hard mask layer over the free layer and the doped region to cover the first region and the second region; and etching the doped region, the free layer, the tunnel barrier layer, and the pinned layer using the hard mask layer.

In another embodiment, a method for fabricating a semiconductor device, may include: forming a magnetic tunnel junction layer over a substrate, the magnetic tunnel junction layer including a pinned layer, a tunnel barrier layer, and a free layer; forming a sacrificial hard mask layer over the free layer to cover at least a first region where a first magnetic tunnel junction pattern is to be formed and to expose at least a second region where a second magnetic tunnel junction structure is to be formed; etching a portion of the free layer exposed by the sacrificial hard mask layer to reduce a thickness of the portion of the free layer; removing the sacrificial hard mask layer; forming a hard mask layer over the free layer to cover the first region and the second region; and etching the free layer, the tunnel barrier layer, and the pinned layer using the hard mask layer.

In another embodiment, a method for fabricating a semiconductor device, may include: forming a magnetic tunnel junction layer over a substrate, the magnetic tunnel junction layer including a pinned layer, a tunnel barrier layer, and a free layer; forming a sacrificial hard mask layer over the free layer to cover at least a first region where a first magnetic tunnel junction layer is to be formed and to expose at least a second region where a second magnetic tunnel junction pattern is to be formed; etching a portion of the free layer exposed by the sacrificial hard mask layer to reduce a thickness of the portion of the free layer; forming a metal oxide layer over the sacrificial hard mask layer and the free layer; removing the sacrificial hard mask layer and a portion of the metal oxide layer that is formed over a sidewall and an upper surface of the sacrificial hard mask layer to form a metal oxide layer; forming a hard mask layer over the free layer and the metal oxide layer to cover a first region where the first magnetic tunnel junction layer is to be formed and a second region where the second magnetic tunnel junction pattern is to be formed; and etching the free layer, the tunnel barrier layer, the pinned layer, and the metal oxide layer using the hard mask layer.

### BRIEF DESCRIPTION OF THE DRAWINGS

FIGS. 1A and 1B are views illustrating a semiconductor device based on some embodiments of the disclosed technology.

FIGS. 2A to 2G are cross-sectional views illustrating a method for fabricating a semiconductor device based on some embodiments of the disclosed technology.

FIGS. 3A to 3F are cross-sectional views illustrating a method for fabricating a semiconductor device based on some embodiments of the disclosed technology.

FIGS. 4A to 4E are cross-sectional views illustrating a method for fabricating a semiconductor device based on some embodiments of the disclosed technology.

### DETAILED DESCRIPTION

Hereinafter, various embodiments of the disclosure will be described in detail with reference to the accompanying drawings.

The drawings are not necessarily drawn to scale. In some instances, proportions of at least some structures in the drawings may have been exaggerated in order to clearly illustrate certain features of the described embodiments. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure might not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

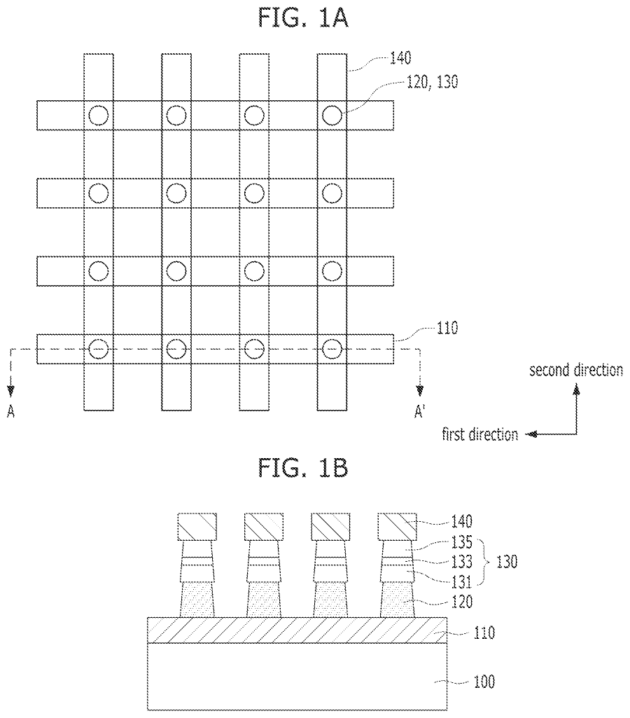

FIGS. 1A and 1B are views illustrating a semiconductor device based on some embodiments of the disclosed technology. FIG. 1A is a plan view, and FIG. 1B is a cross-sectional view taken along a line A-A′ of FIG. 1A.

Referring to FIGS. 1A and 1B, a semiconductor device of some embodiments may include a substrate 100, a plurality of first conductive lines 110 disposed over the substrate 100 and extending in a first direction, a plurality of second conductive lines 140 disposed over the first conductive lines 110 and extending in a second direction intersecting the first direction, and a stacked structure of a selector pattern 120 and a magnetic tunnel junction pattern (magnetic tunnel junction structure) 130 disposed at each of intersection regions of the first conductive lines 110 and the second conductive lines 140, between the first conductive lines 110 and the second conductive lines 140. Here, the first direction and the second direction may correspond to directions substantially parallel to the surface of the substrate 100. A direction substantially perpendicular to the surface of the substrate 100 will hereinafter be referred to as a vertical direction. In some embodiments of the disclosed technology, the term “pattern” can be used to indicate a material layer that is arranged in a particular way. In some embodiments of the disclosed technology, the term “pattern” can be used to indicate a patterned layer in which a certain layer is selective etched or patterned.

The substrate 100 may include a semiconductor material such as silicon. Additionally, a required lower structure (not shown) may be formed within the substrate 100. For example, an integrated circuit for driving the first conductive lines 110 and/or the second conductive lines 140 may be formed within the substrate 100.

The plurality of first conductive lines 110 may be arranged to be spaced apart from each other in the second direction. The first conductive line 110 may include at least one of various conductive materials, for example, a metal such as platinum (Pt), tungsten (W), aluminum (Al), copper (Cu), tantalum (Ta), or titanium (Ti), a metal nitride such as titanium nitride (TiN) or tantalum nitride (TaN), or a combination thereof, and may have a single-layer structure or a multi-layer structure.

The plurality of second conductive lines 140 may be arranged to be spaced apart from each other in the first direction. The second conductive line 140 may include at least one of various conductive materials, for example, a metal such as platinum (Pt), tungsten (W), aluminum (Al), copper (Cu), tantalum (Ta), or titanium (Ti), a metal nitride such as titanium nitride (TiN) or tantalum nitride (TaN), or a combination thereof, and may have a single-layer structure or a multi-layer structure.

The selector pattern 120 may have a pillar shape that overlaps the intersection region of the first conductive line 110 and the second conductive line 140. In some embodiments, the selector pattern 120 may have a circular shape in a plan view, but the disclosed technology is not limited thereto, and the selector pattern 120 may have one of various shapes such as an oval shape, a rectangular shape, or a square shape, in a plan view.

The selector pattern 120 may control access to the magnetic tunnel junction pattern (magnetic tunnel junction structure) 130, and may prevent or reduce current leakage that may occur between the magnetic tunnel junction patterns 130 sharing the first conductive line 110 or the second conductive line 140. To this end, the selector pattern 120 may have a threshold switching characteristic that (1) blocks or reduces/minimizes a current that flows when a magnitude of a voltage applied to upper and lower ends of the selector pattern 120 is less than a predetermined threshold voltage, and (2) allows the current to rapidly increase at a voltage equal to or greater than the threshold voltage. That is, the selector pattern 120 may be turned on at a voltage equal to or greater than the threshold voltage, and may be turned off below the threshold voltage.

The selector pattern 120 may include a diode, an ovonic threshold switching (OTS) material such as a chalcogenide-based material, a mixed ionic electronic conducting (MIEC) material such as a metal-containing chalcogenide-based material, a metal insulator transition (MIT) material such as NbO₂ or VO₂, or a tunneling insulating material with a relatively wide band gap, such as SiO₂ or Al₂O₃.

In some implementations, the selector pattern 120 may include an insulating material layer doped with a dopant. Here, the insulating material layer may include a silicon-containing insulating material such as silicon oxide, silicon nitride, or silicon oxynitride, an insulating metal oxide, an insulating metal nitride, or a combination thereof. In some implementations, there may be a deep trap within the insulating material layer. The deep trap may have an energy level closer to an energy level of a valence band of the insulating material layer than to an energy level of a conduction band of the insulating material layer. The dopant may serve to create a shallow trap that provides a path for the movement of charge carriers, such as electrons or holes, within the insulating material layer. The shallow trap may have an energy level that is closer to the energy level of the conduction band than to the energy level of the valence band of the insulating material layer. As an example, if the insulating material layer contains silicon, the dopant may include a metal with a different valence from silicon, such as gallium (Ga), boron (B), indium (In), phosphorus (P), arsenic (As), antimony (Sb), germanium (Ge), carbon (C), tungsten (W), or a combination thereof. Alternatively, when the insulating material layer contains a metal, the dopant may include another metal having a different valence from the metal, or silicon. As an example, the selector pattern 120 may include arsenic (As) doped silicon oxide, such as arsenic (As) doped silicon dioxide (SiO₂). When a voltage equal to or greater than the threshold voltage is applied to the selector pattern 120, charge carriers trapped in the deep trap may jump into the shallow trap through thermal emission or tunneling, and the charge carriers may move through the shallow trap, and thus the magnetic tunnel junction pattern (magnetic tunnel junction structure) 130 may be in an on-state (turned-on state) that allows a current to flow through the selector pattern 120. On the other hand, when no voltage or a voltage less than the threshold voltage is applied to the selector pattern 120, no or less charge carriers can jump into the shallow trap, and thus the magnetic tunnel junction pattern (magnetic tunnel junction structure) 130 may transition to an off-state (turned-off state) that does not allow a current to flow through the selector pattern 120.

The magnetic tunnel junction pattern 130 may have a pillar shape that overlaps the intersection region of the first conductive line 110 and the second conductive line 140. In some embodiments, the magnetic tunnel junction pattern 130 may have a circular shape in a plan view, but the disclosed technology is not limited thereto, and the magnetic tunnel junction pattern 130 may have one of various shapes, such as an oval shape, a rectangular shape, or a square shape, in a plan view. Additionally, in some embodiments, the selector pattern 120 and the magnetic tunnel junction pattern 130 may be formed by separate patterning processes using different masks. In this case, the selector pattern 120 and the magnetic tunnel junction pattern 130 may overlap each other, but their sidewalls may not be aligned with each other. However, the disclosed technology is not limited thereto, and in another embodiment, the selector pattern 120 and the magnetic tunnel junction pattern 130 may be formed by a single patterning process using a single mask, and accordingly, the selector pattern 120 and the magnetic tunnel junction pattern 130 may overlap each other, and their sidewalls may be aligned with each other.

The magnetic tunnel junction pattern 130 may include a stacked structure of a pinned pattern (pinned layer pattern) 131, a tunnel barrier pattern (tunnel barrier layer pattern) 133, and a free pattern (free layer pattern) 135. The pinned pattern (pinned layer pattern) 131 may be a layer that has a fixed magnetization direction, unlike the magnetization direction of the free pattern (free layer pattern) 135. In this regard, the pinned pattern (pinned layer pattern) 131 may also be called a reference layer. The free pattern (free layer pattern) 135 may be a layer that has a changeable magnetization direction to store different data, and may also be called a storage layer. The pinned pattern (pinned layer pattern) 131 and the free pattern (free layer pattern) 135 may have a magnetization direction substantially parallel to the surface of the layer, or may have a magnetization direction substantially perpendicular to the surface of the layer. The tunnel barrier pattern (tunnel barrier layer pattern) 133 may physically separate the pinned pattern (pinned layer pattern) 131 from the free pattern (free layer pattern) 135, and may enable tunneling of electrons between the pinned pattern (pinned layer pattern) 131 and the free pattern (free layer pattern) 135. The pinned pattern (pinned layer pattern) 131 and the free pattern (free layer pattern) 135 may independently have a single-layer structure or a multi-layer structure including a ferromagnetic material. As an example, the pinned pattern (pinned layer pattern) 131 and the free pattern (free layer pattern) 135 may independently include an alloy containing Fe, Ni, or Co as a main component, such as Fe—Pt alloy, Fe—Pd alloy, Co—Pd alloy, Co—Pt alloy, Fe—Ni—Pt alloy, Co—Fe—Pt alloy, Co—Ni—Pt alloy, and Co—Fe—B alloy, or, a stacked structure of Co/Pt or Co/Pd. The tunnel barrier pattern (tunnel barrier layer pattern) 133 may have a single-layer structure or a multi-layer structure including an insulating material. As an example, the tunnel barrier pattern (tunnel barrier layer pattern) 133 may include an insulating oxide such as MgO, CaO, SrO, TiO, VO, or NbO. The magnetic tunnel junction pattern (magnetic tunnel junction structure) 130 may store different data values by switching between different resistance states depending on the voltage or current applied through the first conductive line 110 and the second conductive line 140. More specifically, when the magnetization direction of the free pattern (free layer pattern) 135 changes depending on the voltage or current applied to the magnetic tunnel junction pattern 130 and becomes parallel to the magnetization direction of the pinned pattern (pinned layer pattern) 131, the magnetic tunnel junction pattern 130 may have a low resistance state, and may store, for example, data bit “1.” On the other hand, when the magnetization direction of the free pattern (free layer pattern) 135 changes depending on the voltage or current applied to the magnetic tunnel junction pattern 130 and becomes anti-parallel to the magnetization direction of the pinned pattern (pinned layer pattern) 131, the magnetic tunnel junction pattern 130 may have a high resistance state, and may store, for example, data bit “0.”

As long as the magnetic tunnel junction pattern (magnetic tunnel junction structure) 130 includes the pinned pattern (pinned layer pattern) 131, the free pattern (free layer pattern) 135 disposed over the pinned pattern (pinned layer pattern) 131, and the tunnel barrier pattern (tunnel barrier layer pattern) 133 between the pinned pattern (pinned layer pattern) 131 and the free pattern (free layer pattern) 135, the structure of the magnetic tunnel junction pattern (magnetic tunnel junction structure) 130 may be modified in various ways. As an example, the free pattern (free layer pattern) 135 may be disposed over the pinned pattern (pinned layer pattern) 131, and the tunnel barrier pattern (tunnel barrier layer pattern) 133 is disposed between the pinned pattern (pinned layer pattern) 131 and the free pattern (free layer pattern) 135. Alternatively, as an example, the magnetic tunnel junction pattern (magnetic tunnel junction structure) 130 may further include one or more layers to improve its characteristics. For example, the magnetic tunnel junction pattern 130 may further include one or more pinned patterns that are anti-ferromagnetically coupled to the pinned pattern (pinned layer pattern) 131 to form a synthetic anti-ferromagnetic (SAF) structure. An SAF coupling pattern containing a non-magnetic material may be interposed between the pinned pattern (pinned layer pattern) 131 and an adjacent pinned pattern (pinned layer pattern), and/or between two adjacent pinned patterns. Alternatively, for example, the magnetic tunnel junction pattern 130 may further include one or more conductive patterns interposed between the pinned pattern (pinned layer pattern) 131 and the first conductive line 110 and/or between the free pattern (free layer pattern) 135 and the second conductive line 140. The conductive pattern may be called an electrode layer, a hard mask layer, or a capping layer, depending on its function.

In the magnetic tunnel junction pattern 130, when the free pattern (free layer pattern) 135 has a magnetization direction substantially perpendicular to the surface of the layer, the perpendicular magnetic anisotropy of the free pattern (free layer pattern) 135 may be inversely proportional to the thickness of the free pattern (free layer pattern) 135. That is, as the thickness of the free pattern (free layer pattern) 135 increases, the perpendicular magnetic anisotropy of the free pattern (free layer pattern) 135 may decrease. On the other hand, as the thickness of the free pattern (free layer pattern) 135 decreases, the perpendicular magnetic anisotropy of the free pattern (free layer pattern) 135 may increase. When the perpendicular magnetic anisotropy increases, data retention characteristics may be improved, but operation speed may be reduced and power consumption may increase. Accordingly, by varying the thicknesses of the free patterns (free layer pattern) 135 in the magnetic tunnel junction patterns 130, the magnetic tunnel junction patterns 130 with different characteristics may be formed over a single substrate 100. That is, it may be possible to implement a semiconductor device that simultaneously includes the magnetic tunnel junction pattern 130 with excellent data retention characteristics because the thickness of the free pattern (free layer pattern) 135 is relatively small, and the magnetic tunnel junction pattern 130 with high operation speed and low power consumption because the thickness of the free pattern (free layer pattern) 135 is relatively large.

As will be discussed below, a semiconductor device may be formed by adjusting the thicknesses of free patterns included in the plurality of magnetic tunnel junction patterns.

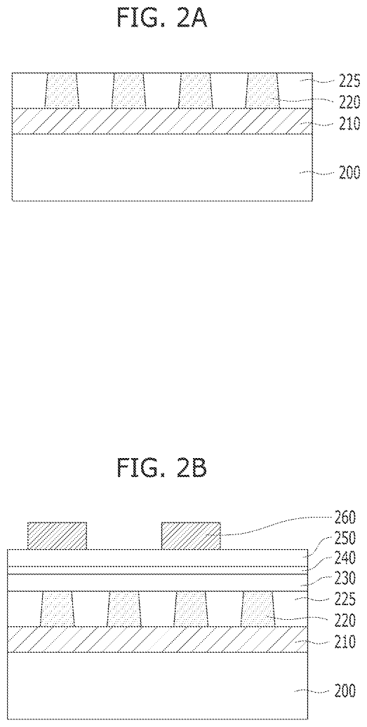

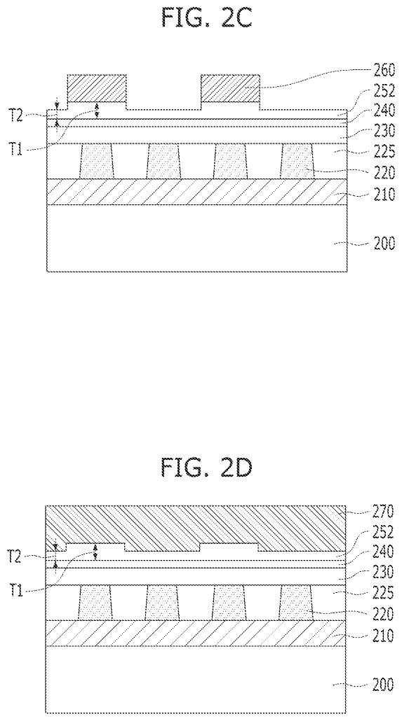

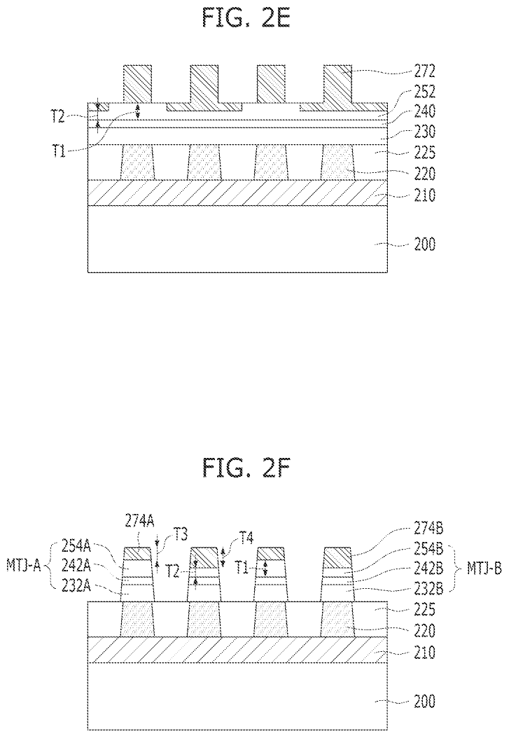

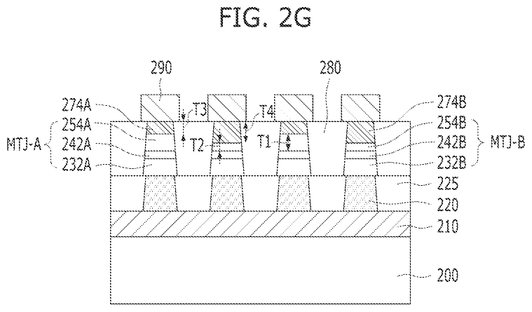

FIGS. 2A to 2G are cross-sectional views illustrating a method for fabricating a semiconductor device based on some embodiments of the disclosed technology. Specifically, FIGS. 2A to 2G are cross-sectional views taken along the line A-A′ in FIG. 1A.

In some embodiments of the disclosed technology, the fabrication method of the semiconductor device discussed above may include the following steps.

Referring to FIG. 2A, a first conductive line 210 extending in a first direction may be formed over a substrate 200. Although not shown, a plurality of first conductive lines 210 may be arranged parallel to each other and spaced apart from each other in a second direction penetrating this cross section. The first conductive line 210 may be formed by depositing a conductive material and patterning the conductive material. Additionally, the space between the first conductive lines 210 in the second direction may be filled with an insulating material (not shown).

Subsequently, a plurality of selector patterns 220 and a first interlayer insulating layer 225 formed in the spaces between the selector patterns 220 may be disposed over the first conductive lines 210 and the insulating material disposed between the first conductive lines 210. In some embodiments, the selector patterns 220 and the first interlayer insulating layer 225 may be formed by forming a selector material for forming the selector patterns 220 over the first conductive lines 210 and the insulating material, selectively etching the selector material to form the selector patterns 220, forming a first interlayer insulating material thick enough to fill the space between the selector patterns 220, and performing a planarization process such as chemical mechanical polishing (CMP) so that the upper surfaces of the selector patterns 220 are exposed. In this case, the selector pattern 220 may have a width that tapers from bottom to top in the vertical direction. However, the disclosed technology is not limited thereto, and in another embodiment, the selector patterns 220 and the first interlayer insulating layer 225 may be formed by forming a first interlayer insulating material over the first conductive lines 210 and the insulating material therebetween, selectively etching the first interlayer insulating material to form the first interlayer insulating layer 225 that provides spaces for the selector patterns 220 to be formed, forming a selector material with a thickness that sufficiently fills the spaces, and performing a planarization process so that the upper surface of the first interlayer insulating layer 225 is exposed. In this case, unlike what is shown in FIG. 2A, the selector pattern 220 may have a width that tapers from top to bottom in the vertical direction.

Referring to FIG. 2B, a magnetic tunnel junction layer including a pinned layer 230, a tunnel barrier layer 240, and a free layer 250 may be formed over the selector patterns 220 and the first interlayer insulating layer 225.

Subsequently, a sacrificial hard mask pattern 260 may be formed over the free layer 250. The sacrificial hard mask pattern 260 may cover at least a region where a first magnetic tunnel junction pattern (see MTJ-A in FIG. 2F) is to be formed, and may expose at least a region where a second magnetic tunnel junction pattern (see MTJ-B in FIG. 2F) is to be formed. The first magnetic tunnel junction pattern and the second magnetic tunnel junction pattern may be spaced apart from each other, and the sacrificial hard mask pattern 260 may not cover the space between the first magnetic tunnel junction pattern and the second magnetic tunnel junction pattern, or may cover a portion of the space between the first magnetic tunnel junction pattern and the second magnetic tunnel junction pattern. On this premise, the horizontal width of the sacrificial hard mask pattern 260 (or the size of the sacrificial hard mask pattern 260) may be modified in various ways.

The sacrificial hard mask pattern 260 may include at least one of various materials that can function as an etch barrier during a subsequent etching process of the free layer 250 of FIG. 2C. Furthermore, the sacrificial hard mask pattern 260 may include a material that is easy to remove. For example, the sacrificial hard mask pattern 260 may include a photoresist that is easy to remove through a strip process or a cleaning process.

Referring to FIG. 2C, an initial free pattern 252 may be formed by etching the free layer 250 to a predetermined depth using the sacrificial hard mask pattern 260 as an etch barrier. Here, the etching depth of the free layer 250 may be smaller than the thickness of the free layer 250. Accordingly, a portion of the initial free pattern 252 that overlaps the sacrificial hard mask pattern 260 may have a first thickness T1, and another portion of the initial free pattern 252 that is exposed by the sacrificial hard mask pattern 260 may have a second thickness T2 that is smaller than the first thickness T1 and greater than 0. The first thickness T1 may be substantially the same as the thickness of the free layer 250.

Referring to FIG. 2D, after removing the sacrificial hard mask pattern 260, a hard mask layer 270 may be formed over the initial free pattern 252. The hard mask layer 270 may be formed to cover all of the portion having the first thickness T1 and the portion having the second thickness T2 of the initial free pattern 252.

Referring to FIG. 2E, an initial hard mask pattern 272 may be formed by patterning the hard mask layer 270.

The initial hard mask pattern 272 may function as an etch barrier during the subsequent etching process to form the magnetic tunnel junction patterns (see MTJ-A and MTJ-B in FIG. 2F), and may be formed to cover the regions where the magnetic tunnel junction patterns are to be formed. Here, the horizontal width of the initial hard mask pattern 272 (or the size of the initial hard mask pattern 272) may be smaller than the horizontal width of the sacrificial hard mask pattern 260 (or the size of the sacrificial hard mask pattern 260). Furthermore, the initial hard mask pattern 272 may remain after the etching process, and may function as a capping layer that protects the magnetic tunnel junction patterns or improves the characteristics of the magnetic tunnel junction patterns, over the magnetic tunnel junction patterns. The initial hard mask pattern 272 may include a conductive material. For example, the initial hard mask pattern 272 may include metal, conductive metal oxide, or conductive metal nitride. The thickness of the initial hard mask pattern 272 over the portion having the first thickness T1 of the initial free pattern 252 may be smaller than the thickness of the initial hard mask pattern 272 over the portion having the second thickness T2 of the initial free pattern 252.

Referring to FIG. 2F, the initial free pattern 252, the tunnel barrier layer 240, and the pinned layer 230 may be etched using the initial hard mask pattern 272 as an etch barrier to form magnetic tunnel junction patterns MTJ-A and MTJ-B including free patterns 254A and 254B, tunnel barrier patterns 242A and 242B, and pinned patterns 232A and 232B. In this process, part of the initial hard mask pattern 272 may be etched away to form hard mask patterns 274A and 274B.

Here, one of the free patterns 254A and 254B may have the first thickness T1 and may be referred to as a first free pattern 254A, and the other one of the free patterns 254A and 254B may have the second thickness T2 and may be referred to as a second free pattern 254B. One of the tunnel barrier patterns 242A and 242B may overlap the first free pattern 254A and may be referred to as a first tunnel barrier pattern 242A, and the other one of the tunnel barrier patterns 242A and 242B may overlap the second free pattern 254B and may be referred to as a second tunnel barrier pattern 242B. One of the pinned patterns 232A and 232B may overlap the first free pattern 254A and may be referred to as a first pinned pattern 232A, and the one of the pinned patterns 232A and 232B may overlap the second free pattern 254B and may be referred to as a second pinned pattern 232B. The first free pattern 254A, the first tunnel barrier pattern 242A, and the first pinned pattern 232A may form a first magnetic tunnel junction pattern MTJ-A, and the second free pattern 254B, the second tunnel barrier pattern 242B, and the second pinned pattern 232B may form a second magnetic tunnel junction pattern MTJ-B. In addition, one of the hard mask patterns 274A and 274B may overlap the first magnetic tunnel junction pattern MTJ-A and may be referred to as a first hard mask pattern 274A, and the other one of the hard mask patterns 274A and 274B may overlap the second magnetic tunnel junction pattern MTJ-B and may be referred to as a second hard mask pattern 274B.

The height of the upper surface of the first hard mask pattern 274A and the height of the upper surface of the second hard mask pattern 274B from the surface of the substrate 200 may be substantially the same as each other. Since the first thickness T1 of the first free pattern 254A is greater than the second thickness T2 of the second free pattern 254B, the third thickness T3 of the first hard mask pattern 274A may be smaller than the fourth thickness T4 of the second hard mask pattern 274B.

Referring to FIG. 2G, a second interlayer insulating layer 280 may be formed by forming an insulating material that covers the process result of FIG. 2F, and performing a planarization process so that the upper surfaces of the first and second hard mask patterns 274A and 274B are exposed.

Subsequently, a plurality of second conductive lines 290 extending in the second direction may be formed over the first and second hard mask patterns 274A and 274B and the second interlayer insulating layer 280.

In this way, the semiconductor device may be implemented as shown in FIG. 2G.

Referring again to FIG. 2G, the semiconductor device implemented based on some embodiments may include the substrate 200, the plurality of first conductive lines 210 disposed over the substrate 200 and extending in the first direction, the plurality of second conductive lines 290 disposed over the first conductive lines 210 and extending in the second direction intersecting the first direction, and the magnetic tunnel junction patterns MTJ-A and MJT-B and the selector patterns 220 that are disposed between the first conductive lines 210 and the second conductive lines 290 and overlap the intersection regions of the first conductive lines 210 and the second conductive lines 290.

The magnetic tunnel junction patterns MTJ-A and MTJ-B may include the first magnetic tunnel junction pattern MTJ-A including the first free pattern 254A having the first thickness T1 at its uppermost portion, and the second magnetic tunnel junction pattern MTJ-B including the second free pattern 254B having the second thickness T2 at its uppermost portion. The second thickness T2 may be smaller than the first thickness T1.

The first hard mask pattern 274A having the third thickness T3 may be interposed between the first magnetic tunnel junction pattern MTJ-A and the second conductive line 290, and the second hard mask pattern 274B having the fourth thickness T4 greater than the third thickness T3 may be interposed between the second magnetic tunnel junction pattern MTJ-B and the second conductive line 290. The sum of the first thickness T1 and the third thickness T3 may be substantially equal to the sum of the second thickness T2 and the fourth thickness T4.

In some embodiments, since the first magnetic tunnel junction pattern MTJ-A includes the first free pattern 254A with a relatively large thickness and the second magnetic tunnel junction pattern MTJ-B includes the second free pattern 254B with a relatively small thickness, the first magnetic tunnel junction pattern MTJ-A and the second magnetic tunnel junction pattern MTJ-B may have different characteristics from each other. For example, the first magnetic tunnel junction pattern MTJ-A may have a faster operating speed and lower power consumption compared to the second magnetic tunnel junction pattern MTJ-B, and the second magnetic tunnel junction pattern MTJ-B may have excellent data retention characteristics compared to the first magnetic tunnel junction pattern MTJ-A. As a result, the semiconductor device including the magnetic tunnel junction patterns MTJ-A and MTJ-B with different characteristics may be implemented through easy processes.

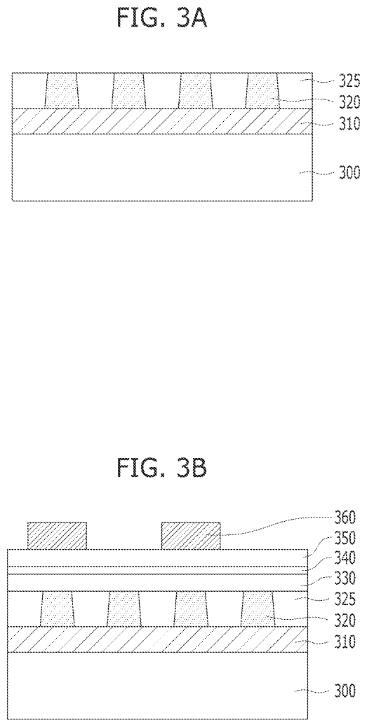

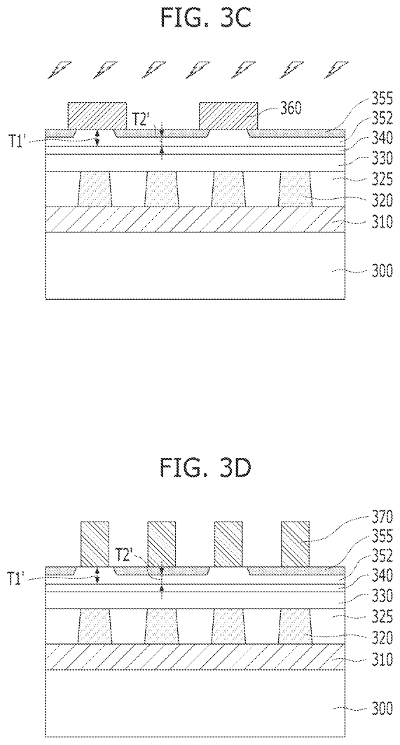

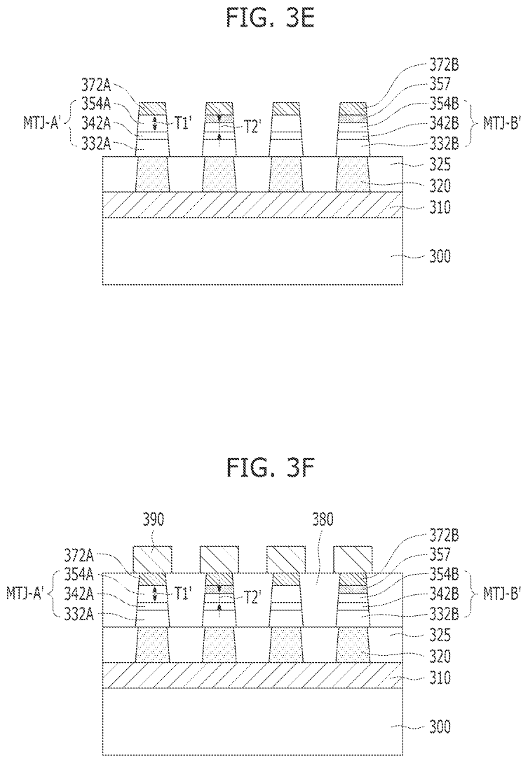

FIGS. 3A to 3F are cross-sectional views illustrating a method for fabricating a semiconductor device based on some embodiments of the disclosed technology. Specifically, FIGS. 3A to 3F are cross-sectional views taken along the line A-A′ in FIG. 1A.

In some embodiments of the disclosed technology, the fabrication method of the semiconductor device discussed above may include the following steps.

Referring to FIG. 3A, a first conductive line 310 extending in a first direction may be formed over a substrate 300. Although not shown, a plurality of first conductive lines 310 may be arranged parallel to each other and spaced apart from each other in a second direction penetrating this cross section.

Subsequently, selector patterns 320 and a first interlayer insulating layer 325 filled between the selector patterns 320 may be formed over the first conductive lines 310 and an insulating material filled between the first conductive lines 310.

Referring to FIG. 3B, a magnetic tunnel junction layer including a pinned layer 330, a tunnel barrier layer 340, and a free layer 350 may formed over the selector patterns 320 and the first interlayer insulating layer 325.

Subsequently, a sacrificial hard mask pattern 360 may be formed over the free layer 350. The sacrificial hard mask pattern 360 may cover at least a region where a first magnetic tunnel junction pattern (see MTJ-A′ in FIG. 3E) is to be formed, and may expose at least a region where a second magnetic tunnel junction pattern (see MTJ-B′ in FIG. 3E) is to be formed. On this premise, the horizontal width of the sacrificial hard mask pattern 360 (and/or the size of the sacrificial hard mask pattern 360) may be modified in various ways.

The sacrificial hard mask pattern 360 may include at least one of various materials that may function to protect the portion covered by the sacrificial hard mask pattern 360 from etching chemicals during the subsequent doping process of FIG. 3C. Furthermore, the sacrificial hard mask pattern 360 may include a material that is easy to remove, for example, a photoresist that is easy to remove through a strip process or a cleaning process.

Referring to FIG. 3C, a doped layer 355 may be formed in the free layer 350 by doping a predetermined dopant into the free layer 350 using the sacrificial hard mask pattern 360 as a doping mask. The remaining portion of the free layer 350, excluding the doped layer 355, will hereinafter be referred to as an initial free pattern 352.

Here, the doping depth and the thickness of the doped layer 355 formed accordingly may be smaller than the thickness of the free layer 350. Accordingly, a portion of the initial free pattern 352 that overlaps the sacrificial hard mask pattern 360 may have a first thickness T1′, and another portion of the initial free pattern 352 that is exposed by the sacrificial hard mask pattern 360 and is located below the doped layer 355 may have a second thickness T2′ that is smaller than the first thickness T1′ and greater than 0. The first thickness T1′ may be substantially the same as the thickness of the free layer 350.

In some implementations, an ion implantation process may be used as a doping method. The predetermined dopant may include an element that can maintain the electrical conductivity of the free layer 350 while reducing, removing or minimizing the magnetism of the free layer 350. Accordingly, the doped layer 355 may be formed of a material containing a constituent element of the free layer 350 and an element used as a dopant, and may be a magnetic loss region and a conductive region. As an example, the dopant may include an inert element such as Ar. In some implementations, the doped layer 355 may be in an amorphous state.

Referring to FIG. 3D, after removing the sacrificial hard mask pattern 360, an initial hard mask pattern 370 may be formed over the initial free pattern 352 and the doped layer 355. In some implementations, in order to flatten the surfaces of the initial free pattern 352 and the doped layer 355, a planarization process may be further performed before the formation process of the initial hard mask pattern 370.

The initial hard mask pattern 370 may function as an etch barrier during the etching process to form magnetic tunnel junction patterns (see MTJ-A′ and MTJ-B′ in FIG. 3E), and may be formed to cover regions where the magnetic tunnel junction patterns are to be formed. Furthermore, the initial hard mask pattern 370 may remain after the etching process, and may function as a capping layer that protects the magnetic tunnel junction patterns or improves the characteristics of the magnetic tunnel junction patterns. The initial hard mask pattern 370 may be located over the portion having the first thickness T1 of the initial free pattern 352 and the doped layer 355, and may have a substantially constant thickness.

Referring to FIG. 3F, the doped layer 355, the initial free pattern 352, the tunnel barrier layer 340, and the pinned layer 330 may be etched using the initial hard mask pattern 270 as an etch barrier to form magnetic tunnel junction patterns MTJ-A′ and MTJ-B′ including free patterns 354A and 354B, tunnel barrier patterns 342A and 342B, and pinned patterns 332A and 332B. In this process, part of the initial hard mask pattern 370 may be etched away to form hard mask patterns 372A and 372B.

Here, one of the free patterns 354A and 354B may have the first thickness T1′ and may be referred to as a first free pattern 354A, and the other one of the free patterns 354A and 354B may have the second thickness T2′ and may be referred to as a second free pattern 354B. One of the tunnel barrier patterns 342A and 342B may overlap the first free pattern 354A and may be referred to as a first tunnel barrier pattern 342A, and the other one of the tunnel barrier patterns 342A and 342B may overlap the second free pattern 354B and may be referred to as a second tunnel barrier pattern 342B. One of the pinned patterns 332A and 332B may overlap the first free pattern 354A and may be referred to as a first pinned pattern 332A, and the other one of the pinned patterns 332A and 332B may overlap the second free pattern 354B and may be referred to as a second pinned pattern 332B. The first free pattern 354A, the first tunnel barrier pattern 342A, and the first pinned pattern 332A may form a first magnetic tunnel junction pattern MTJ-A′, and the second free pattern 354B, the second tunnel barrier pattern 342B, and the second pinned pattern 332B may form a second magnetic tunnel junction pattern MTJ-B′. In addition, one of the hard mask patterns 372A and 372B may overlap the first magnetic tunnel junction pattern MTJ-A′ and may be referred to as a first hard mask pattern 372A, and the other one of the hard mask patterns 372A and 372B may overlap the second magnetic tunnel junction pattern MTJ-B′ and may be referred to as a second hard mask pattern 372B. The first free pattern 354A and the first hard mask pattern 372A may be in direct contact with each other. On the other hand, a doped pattern or layer 357 may be interposed between the second free pattern 354B and the second hard mask pattern 372B. The doped pattern 357 can be made or structured to be electrically conductive to provide an electrical connection between the second free pattern 354B and the second hard mask pattern 372B. In some implementations, the doped pattern 357 may be configured to be non-magnetic and in an amorphous state, and thus even if it is disposed on the second free pattern 354B, it may not have a negative effect on the characteristics of the second free pattern 354B, such as perpendicular magnetic anisotropy of the second free pattern 354B.

Referring to FIG. 3F, a second interlayer insulating layer 380 may be formed by forming an insulating material covering the process result of FIG. 3E, and performing a planarization process so that the upper surfaces of first and second hard mask patterns 372A and 372B are exposed.

Subsequently, a plurality of second conductive lines 390 extending in the second direction may be formed over the first and second hard mask patterns 372A and 372B and the second interlayer insulating layer 380.

In this way, the semiconductor device may be implemented as shown in FIG. 3F.

Referring again to FIG. 3F, the semiconductor device of some embodiments may include the substrate 300, the plurality of first conductive lines 310 disposed over the substrate 300 and extending in the first direction, the plurality of second conductive lines 390 disposed over the first conductive lines 310 and extending in the second direction, and the selector patterns 320 and the magnetic tunnel junction patterns MTJ-A′ and MJT-B′ disposed between the first conductive lines 310 and the second conductive lines 390 and overlapping the intersection regions of the first conductive lines 310 and the second conductive lines 390.

The magnetic tunnel junction patterns MTJ-A′ and MTJ-B′ may include the first magnetic tunnel junction pattern MTJ-A′ including the first free pattern 354A having the first thickness T1′ at its uppermost portion, and the second magnetic tunnel junction pattern MTJ-B′ including the second free pattern 354B having the second thickness T2′ that is less than the first thickness T1′ at its uppermost portion.

The first and second hard mask patterns 372A and 372B may be interposed between the first magnetic tunnel junction pattern MTJ-A′ and the second conductive line 390 and between the second magnetic tunnel junction pattern MTJ-B′ and the second conductive line 390, respectively. Furthermore, the doped pattern 357 may be further interposed between the second magnetic tunnel junction pattern MTJ-B′ and the second hard mask pattern 372B. The doped pattern 357 may include a constituent element of the free patterns 354A and 354B and the dopant, and may have non-magnetic and conductive properties. The sum of the second thickness T2′ of the second free pattern 354B and the thickness of the doped pattern 357 may be substantially equal to the first thickness T1′ of the first free pattern 354A.

The disclosed technology can be implemented in some embodiments to provide a semiconductor device including the magnetic tunnel junction patterns MTJ-A′ and MTJ-B′ with different characteristics through easy processes.

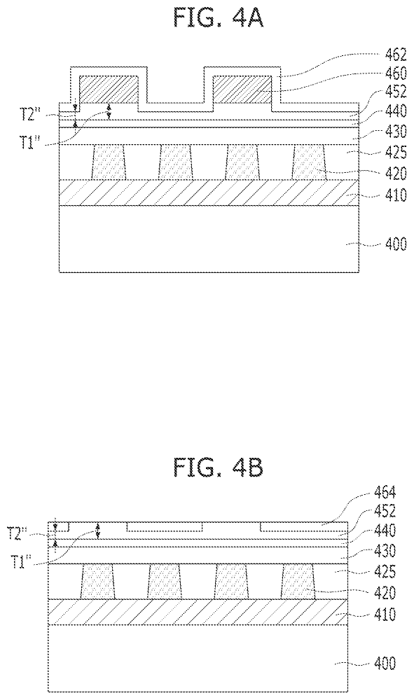

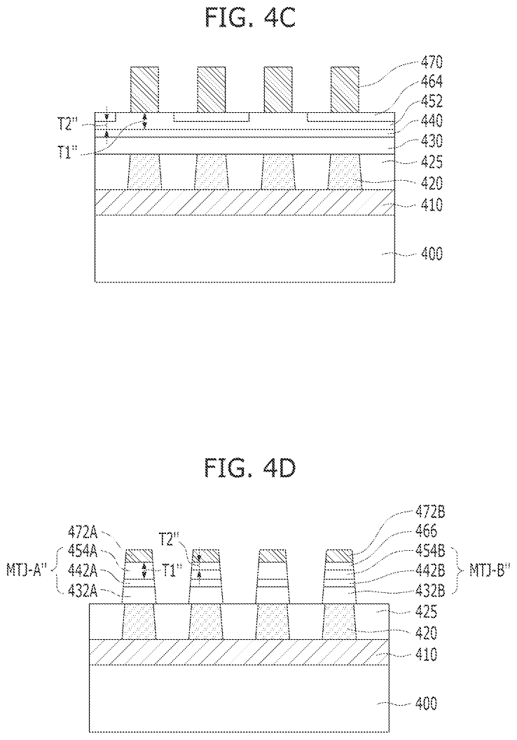

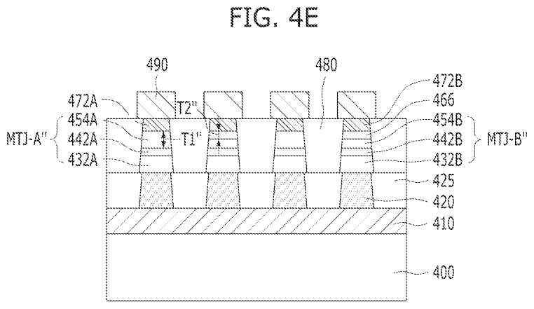

FIGS. 4A to 4E are cross-sectional views illustrating a method for fabricating a semiconductor device based on some embodiments of the disclosed technology. Specifically, FIGS. 4A to 4E are cross-sectional views taken along the line A-A′ in FIG. 1A.

In some embodiments of the disclosed technology, the fabrication method of the semiconductor device discussed above may include the following steps.

Referring to FIG. 4A, a first conductive line 410 extending in a first direction may be formed over a substrate 400. Although not shown, a plurality of first conductive lines 410 may be arranged parallel to each other and spaced apart from each other in a second direction penetrating this cross section.

Subsequently, selector patterns 420 and a first interlayer insulating layer 425 formed in the spaces between the selector patterns 420 may be disposed over the first conductive lines 410 and an insulating material filled between the first conductive lines 410.

Subsequently, a magnetic tunnel junction layer including a pinned layer 430, a tunnel barrier layer 440, and a free layer may be formed over the selector patterns 420 and the first interlayer insulating layer 425, a sacrificial hard mask pattern 460 may be formed over the free layer, and the free layer may be etched to a predetermined depth using the sacrificial hard mask pattern 460 as an etch barrier to from an initial free pattern 452. The sacrificial hard mask pattern 460 may cover at least a region where a first magnetic tunnel junction pattern (see MTJ-A″ in FIG. 4D) is to be formed, and may expose at least a region where a second magnetic tunnel junction pattern (see MTJ-B″ in FIG. 4D) is to be formed. A portion of the initial free pattern 452 that overlaps the sacrificial hard mask pattern 460 may have a first thickness T1″, and another portion of the initial free pattern 452 that is exposed by the sacrificial hard mask pattern 460 may have a second thickness T2″ that is less than the first thickness T1″ and greater than 0.

Subsequently, a metal oxide layer 462 may be formed over the initial free pattern 452 and the sacrificial hard mask pattern 460 along the profile of a structure thereunder. The metal oxide layer 462 may be deposited by at least one of various deposition methods, and may include a non-magnetic metal element and oxygen. As an example, the non-magnetic metal element of the metal oxide layer 462 may include at least one of Ta, Ti, Mg, Hf, Zr, W, and Mo. The metal oxide layer 462 may have a thickness equal to or greater than the difference between the first thickness T1″ and the second thickness T2″. Additionally, the metal oxide layer 462 may have conductive properties.

Referring to FIG. 4B, a planarization process, such as CMP, may be performed to expose the upper surface of the portion having the first thickness T1″ of the initial free pattern 452. As a result, the sacrificial hard mask pattern 460 and a portion of the metal oxide layer 462 that is located over the upper surface and the sidewall of the sacrificial hard mask pattern 460 may be removed, and another portion of the metal oxide layer 462 that is located over the portion having the second thickness T2″ of the initial free pattern 452 may remain to form an initial metal oxide pattern 464. The upper surface of the portion having the first thickness T1″ of the initial free pattern 452 and the upper surface of the initial metal oxide pattern 464 may be located at substantially the same height.

Referring to FIG. 4C, an initial hard mask pattern 470 may be formed over the initial free pattern 452 and the initial metal oxide pattern 464.

The initial hard mask pattern 470 may function as an etch barrier during the etching process to form magnetic tunnel junction patterns (see MTJ-A″ and MTJ-B″ in FIG. 4D), and may be formed to cover the regions where magnetic tunnel junction patterns are to be formed. Furthermore, the initial hard mask pattern 470 may remain after the etching process, and may function as a capping layer that protects the magnetic tunnel junction patterns or improves the characteristics of the magnetic tunnel junction patterns. The initial hard mask pattern 470 may be located over the portion of the initial free pattern 452 having the first thickness T1″ and the initial metal oxide pattern 464, and may have a substantially constant thickness.

Referring to FIG. 4D, the initial metal oxide pattern 464, the initial free pattern 452, the tunnel barrier layer 440, and the pinned layer 430 may be etched using the initial hard mask pattern 470 as an etch barrier to form magnetic tunnel junction patterns MTJ-A″ and MTJ-B″ including free patterns 454A and 454B, tunnel barrier patterns 442A and 442B, and pinned patterns 432A and 432B may be formed. In this process, part of the initial hard mask pattern 470 may be etched away to form hard mask patterns 472A and 472B.

Here, one of the free patterns 454A and 454B may have the first thickness T1″ and may be referred to as a first free pattern 454A, and the other one of the free patterns 454A and 454B may have the second thickness T2″ and may be referred to as a second free pattern 454B. One of the tunnel barrier patterns 442A and 442B may overlap the first free pattern 454A and may be referred to as a first tunnel barrier pattern 442A, and the other one of the tunnel barrier patterns 442A and 442B may overlap the second free pattern 454B and may be referred to as a second tunnel barrier pattern 442B. One of the pinned patterns 432A and 432B may overlap the first free pattern 454A and may be referred to as a first pinned pattern 432A, and the other one of the pinned patterns 432A and 432B may overlap the second free pattern 454B and may be referred to as a second pinned pattern 432B. The first free pattern 454A, the first tunnel barrier pattern 442A, and the first pinned pattern 432A may form a first magnetic tunnel junction pattern MTJ-A″, and the second free pattern 454B, the second tunnel barrier pattern 442B, and the second pinned pattern 432B may form a second magnetic tunnel junction pattern MTJ-B″. In addition, one of the hard mask patterns 472A and 472B may overlap the first magnetic tunnel junction pattern MTJ-A″ and may be referred to as a first hard mask pattern 472A, and the other one of the hard mask patterns 472A and 472B may overlap the second magnetic tunnel junction pattern MTJ-B″ and may be referred to as a second hard mask pattern 472B. The first free pattern 454A and the first hard mask pattern 472A may be in direct contact with each other. On the other hand, the metal oxide pattern 466 may be interposed between the second free pattern 454B and the second hard mask pattern 472B. Since the metal oxide pattern 466 is conductive, it may provide an electrical connection between the second free pattern 454B and the second hard mask pattern 472B. Furthermore, the metal oxide pattern 466 may be bonded to the second free pattern 454B to improve the perpendicular magnetic anisotropy of the second free pattern 454B. The perpendicular magnetic anisotropy may result from the combination of a metal element, such as iron (Fe), of the second free pattern 454B and oxygen of the metal oxide pattern 466.

Referring to FIG. 4E, a second interlayer insulating layer 480 may be formed by forming an insulating material that covers the process result of FIG. 4D, and performing a planarization process so that until the upper surfaces of the first and second hard mask patterns 472A and 472B are exposed.

Subsequently, a plurality of second conductive lines 490 extending in the second direction may be formed over the first and second hard mask patterns 472A and 472B and the second interlayer insulating layer 480.

In this way, a semiconductor device may be implemented as shown in FIG. 4E.

Referring again to FIG. 4E, the semiconductor device of some embodiments may include the substrate 400, the plurality of first conductive lines 410 disposed over the substrate 400 and extending in the first direction, the plurality of second conductive lines 490 disposed over the first conductive lines 410 and extending in the second direction, and the selector pattern 420 and the magnetic tunnel junction patterns MTJ-A″ and MJT-B″ interposed between the first conductive lines 410 and the second conductive lines 490 and overlapping the intersection regions of the first conductive lines 410 and the second conductive lines 490.

The magnetic tunnel junction patterns MTJ-A″ and MTJ-B″ may include the first magnetic tunnel junction pattern MTJ-A″ including the first free pattern 454A having the first thickness T1″ at its uppermost portion, and the second magnetic tunnel junction pattern MTJ-B″ including the second free pattern 454B having the second thickness T2″ smaller than the first thickness T1″ at its uppermost portion.

The first and second hard mask patterns 472A and 472B may be interposed between the first magnetic tunnel junction pattern MTJ-A″ and the second conductive line 490 and between the second magnetic tunnel junction pattern MTJ-B″ and the second conductive line 490, respectively. Furthermore, the metal oxide pattern 466 may be further interposed between the second magnetic tunnel junction pattern MTJ-B″ and the second hard mask pattern 472B. The metal oxide pattern 466 may be conductive, and may improve the perpendicular magnetic anisotropy of the second free pattern 454B. The sum of the second thickness T2″ of the second free pattern 454B and the thickness of the metal oxide pattern 466 may be substantially the same as the first thickness T1″ of the first free pattern 454A.

In some embodiments, it may be possible to implement a semiconductor device including the magnetic tunnel junction patterns MTJ-A″ and MTJ-B″ with different characteristics through easy processes.

The disclosed technology can be implemented in some embodiments to provide a semiconductor device that can differently adjust thicknesses of free patterns included in a plurality of magnetic tunnel junction patterns through easy processes, and a method for fabricating the same.

While the disclosed technology has been illustrated and described with respect to specific embodiment, it should be understood that various enhancements and modifications of the disclosed embodiments and other embodiments may be made based on what is described and illustrated in this patent document.

1. A semiconductor device comprising:
a substrate;
a first magnetic tunnel junction structure disposed over a portion of the substrate and including a first free layer;
a first hard mask layer disposed over the first free layer of the first magnetic tunnel junction structure;
a second magnetic tunnel junction structure disposed over another portion of the substrate and including a second free layer having a thickness smaller than a thickness of the first free layer;
a second hard mask layer disposed over the second free layer of the second magnetic tunnel junction structure; and
a doped layer interposed between the second free layer of the second magnetic tunnel junction structure and the second hard mask layer and configured to exhibit an electrical conductivity.

2. The semiconductor device according to claim 1, wherein the first free layer and the first hard mask layer are in direct contact with each other.

3. The semiconductor device according to claim 1, wherein the doped layer includes a constituent element of the first free layer and a dopant that decreases, or causes a loss of, a magnetism of the first free layer.

4. The semiconductor device according to claim 3, wherein the dopant includes an inert element.

5. The semiconductor device according to claim 1, wherein the doped layer has an amorphous state.

6. The semiconductor device according to claim 1, wherein a thickness of the first free layer is equal to a sum of a thickness of the second free layer and a thickness of the doped layer.

7. The semiconductor device according to claim 1, further comprising:
a plurality of first conductive lines disposed over the substrate and extending in a first direction; and
a plurality of second conductive lines disposed over the first conductive lines and extending in a second direction intersecting the first direction,
wherein a first stacked structure of the first magnetic tunnel junction structure and the first hard mask layer is disposed between the first conductive lines and the second conductive lines and overlaps an intersection region of a plurality of intersection regions between the first conductive lines and the second conductive lines, and
a second stacked structure of the second magnetic tunnel junction structure, the doped layer, and the second hard mask layer is disposed between the first conductive lines and the second conductive lines and overlaps another intersection region of the plurality of intersection regions between the first conductive lines and the second conductive lines.

8. The semiconductor device according to claim 7, further comprising:
a selector layer disposed between the first conductive line and the first magnetic tunnel junction structure, and between the first conductive line and the second magnetic tunnel junction structure.

9. A semiconductor device comprising:
a substrate;
a first magnetic tunnel junction structure disposed over a portion of the substrate and including a first free layer;
a first hard mask layer disposed over the first free layer;
a second magnetic tunnel junction structure disposed over another portion of the substrate and including a second free layer having a thickness smaller than a thickness of the first free layer; and
a second hard mask layer disposed over the second free layer,
wherein a thickness of the first hard mask layer is smaller than a thickness of the second hard mask layer.

10. The semiconductor device according to claim 9, wherein a sum of the thickness of the first free layer and the thickness of the first hard mask layer is equal to a sum of the thickness of the second free layer and the thickness of the second hard mask layer.

11. The semiconductor device according to claim 9, further comprising:
a plurality of first conductive lines disposed over the substrate and extending in a first direction; and
a plurality of second conductive lines disposed over the first conductive lines and extending in a second direction intersecting the first direction,
wherein a first stacked structure of the first magnetic tunnel junction structure and the first hard mask layer is disposed between the first conductive lines and the second conductive lines and overlaps an intersection region of a plurality of intersection regions between the first conductive lines and the second conductive lines, and
a second stacked structure of the second magnetic tunnel junction structure and the second hard mask layer is disposed between the first conductive lines and the second conductive lines and overlaps another intersection region of the plurality of intersection regions between the first conductive lines and the second conductive lines.

12. The semiconductor device according to claim 11, further comprising:
a selector layer disposed between the first conductive line and the first magnetic tunnel junction structure, and between the first conductive line and the second magnetic tunnel junction structure.

13. A method for fabricating a semiconductor device, comprising:
forming a magnetic tunnel junction layer over a substrate, the magnetic tunnel junction layer including a pinned layer, a tunnel barrier layer, and a free layer;
forming a sacrificial hard mask layer over the free layer to cover at least a first region where a first magnetic tunnel junction structure is to be formed and to expose at least a second region where a second magnetic tunnel junction structure is to be formed;
forming a doped region having a thickness smaller than a thickness of the free layer by doping a portion of the free layer exposed by the sacrificial hard mask layer with a dopant that decreases a magnetism of the free layer;
removing the sacrificial hard mask layer;
forming a hard mask layer over the free layer and the doped region to cover the first region and the second region; and
etching the doped region, the free layer, the tunnel barrier layer, and the pinned layer using the hard mask layer.

14. The method according to claim 13, wherein the dopant includes an inert element.

15. The method according to claim 13, wherein the doped region has an amorphous state.

16. The method according to claim 13, wherein the first magnetic tunnel junction structure includes the pinned layer, the tunnel barrier layer, and the free layer, and
the second magnetic tunnel junction structure includes the pinned layer, the tunnel barrier layer, the free layer, and the doped region.

17. A method for fabricating a semiconductor device, comprising:
forming a magnetic tunnel junction layer over a substrate, the magnetic tunnel junction layer including a pinned layer, a tunnel barrier layer, and a free layer;
forming a sacrificial hard mask layer over the free layer to cover at least a first region where a first magnetic tunnel junction structure is to be formed and to expose at least a second region where a second magnetic tunnel junction structure is to be formed;
etching a portion of the free layer exposed by the sacrificial hard mask layer to reduce a thickness of the portion of the free layer;
removing the sacrificial hard mask layer;
forming a hard mask layer over the free layer to cover the first region and the second region; and
etching the free layer, the tunnel barrier layer, and the pinned layer using the hard mask layer.

18. The method according to claim 17, wherein a thickness of the free layer of the first magnetic tunnel junction structure is greater than a thickness of the free layer of the second magnetic tunnel junction structure, and
a thickness of the hard mask layer overlapping the first magnetic tunnel junction structure is smaller than a thickness of the hard mask layer overlapping the second magnetic tunnel junction structure.

19. A method for fabricating a semiconductor device, comprising:
forming a magnetic tunnel junction layer over a substrate, the magnetic tunnel junction layer including a pinned layer, a tunnel barrier layer, and a free layer;
forming a sacrificial hard mask layer over the free layer to cover at least a first region where a first magnetic tunnel junction layer is to be formed and to expose at least a second region where a second magnetic tunnel junction layer is to be formed;
etching a portion of the free layer exposed by the sacrificial hard mask layer to reduce a thickness of the portion of the free layer;
forming a metal oxide layer over the sacrificial hard mask layer and the free layer;
removing the sacrificial hard mask layer and a portion of the metal oxide layer that is formed over a sidewall and an upper surface of the sacrificial hard mask layer to form a metal oxide layer;
forming a hard mask layer over the free layer and the metal oxide layer to cover a first region where the first magnetic tunnel junction layer is to be formed and a second region where the second magnetic tunnel junction layer is to be formed; and
etching the free layer, the tunnel barrier layer, the pinned layer, and the metal oxide layer using the hard mask layer.

20. The method according to claim 19, wherein the first magnetic tunnel junction layer includes the pinned layer, the tunnel barrier layer, and the free layer, and
the second magnetic tunnel junction layer includes the pinned layer, the tunnel barrier layer, the free layer, and the metal oxide layer.
